(19) United States
(12) Patent Application Publication
(10) Pub. No.: US 2005/0029680 A1
(43) Pub. Date: Feb. 10, 2005

(54) Method and apparatus for the integration of electronics in textiles

(75) Inventors: Stefan Jung, Munich (DE); Christl Lauterbach, Hohenkirchen-Siegertsbrunn (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 10/896,366

(22) Filed: Jul. 21, 2004

Related U.S. Application Data
(63) Continuation of application No. PCT/EP02/13746, filed on Dec. 4, 2002.

(30) Foreign Application Priority Data
Jan. 21, 2002 (DE) 102 02 123.6

(51) Int. Cl. H01L 21/44

(52) U.S. Cl. 257/787

(57) ABSTRACT

Apparatus having at least one textile material in which at least one flexible, wire-like and/or thread-like electric conductor is arranged, at least one electronic component which has at least one electrically conductive contact point which is connected electrically to the conductor, at least a first hard encapsulation which covers and mechanically stabilizes at least the contact point of the component, and at least a second encapsulation, which is designed such that it permits a mechanical connection of the component to the textile material, wherein the second encapsulation comprises a silicone, a polyurethane and/or a textile adhesive.

### CROSS-REFERENCE TO RELATED APPLICATION

This application is a continuation of International Patent Application Serial No. PCT/EP02/13746, filed Dec. 4, 2002, which published in German on Jul. 24, 2003 as WO 03/059101, and is incorporated herein by reference in its entirety.

### FIELD OF THE INVENTION

The present invention relates to a method and apparatus for the integration of electronics in textiles.

### BACKGROUND OF THE INVENTION

The integration of electronic systems in a textile environment has achieved increasing importance in recent times. For example, an increasing demand for textile clothing and accessories has to be recorded which, in addition to their traditional functions, such as a thermal or protective effect and status symbol characteristics, can also fulfill additional functions such as healthcare, personal safety and communication. Numerous conceivable applications of “intelligent clothing” (smart clothes) can be implemented by means of the integration of electronic components and electronic modules in textiles.

Previous approaches to integrate electronics into textile surroundings are restricted to sewing in commercially available electronic modules, such as sewing in small electronic computers (palmtops, mobile telephones, GPS systems or MP3 players) and “laying” conventional connecting cables in “textile cable ducts” in clothing specifically tailor-made for that purpose. However, such attempts to integrate electronic components in a textile environment leads to a considerable impairment of the properties of use of the textile. For example, the commercially available electronic modules in the textile environment are not very flattering and stiffen the otherwise flexible textile material in a disruptive manner. Furthermore, such integration measures do not permit the resultant products to be subjected to conventional textile care. In particular, products of this type are not resistant to a washing, cleaning and ironing procedure.

### SUMMARY OF THE INVENTION

It is an object of the invention to specify an apparatus which permits improved integration of electronic components in a textile environment. It is also an object to specify an appropriate method for connecting an electronic component to a textile material.

According to the invention, an apparatus comprises
at least one textile material in which at least one flexible, wire-like and/or thread-like electric conductor is arranged;
at least one electronic component which has at least one electrically conductive contact point which is connected electrically to the conductor;
at least a first hard encapsulation which covers and mechanically stabilizes at least the contact point of the component; and
at least a second encapsulation, which is designed in such a way that it permits a mechanical connection of the component to the textile material.

The electronic component which is intended to be integrated in the textile environment can be, for example, a one-layer or multi-layer epoxy circuit board, a ceramic board or the like, which is fitted on one or both sides with the electronic components, conductor tracks and also contact points for power supply and data input and output. In order that the electronic component is as small as possible and stiffens only a small area of the textile material, it is preferably fitted on both sides, if necessary. The at least one contact point of the electronic component is electrically conductively connected to the at least one flexible, wire-like and/or thread-like electric conductor of the textile material.

The invention proposes a structure having two encapsulations, in order to connect the component to the textile material in such a way that the apparatus according to the invention can withstand typical stresses during use. The first hard encapsulation is provided in particular in a contact point region of the electronic component, in order to protect the electric connection of the contact point to a conductor track or a metal wire, in particular with regard to mechanical stresses. Since electronic components typically comprise rigid substrate materials such as circuit boards or semiconductor wafers but the textile material has flexible characteristics, the transition point between rigid component and flexible material is particularly stressed. The first encapsulation preferably also leads to watertight sealing of the contact point region.

On the other hand, the second encapsulation, which, like the first encapsulation, does not have to surround the component completely, does not have its main function in the mechanical and possibly chemical protection of the contact point region. Instead, the second encapsulation is designed in such a way that it permits simple and secure mechanical connection of the component to the textile material. Thus, the requirements which have to be placed on the second encapsulation are different from those of the first encapsulation, so that more suitable materials can be selected for the purposes of the mechanical connection between the component and the textile material.

The first encapsulation preferably surrounds the component completely. If the component is, for example, a circuit board fitted with individual electronic components, then the first encapsulation surrounds both the individual electronic components and the contact points of the component, to which electric conductor tracks or electrically conductive wires are connected. Such complete encapsulation of the electronic component with the connecting region of the electric feed lines ensures high mechanical and chemical resistance of the apparatus according to the invention.

The second encapsulation preferably surrounds the component with the first encapsulation completely. The component, which, for example, is surrounded by the first hard encapsulation only in its contact point regions, is thus preferably surrounded completely by the second encapsulation. Since the second encapsulation is designed in such a way that it permits simple mechanical connection of the component contained to the textile material, the complete second encapsulation permits a particularly good possibility of integration into the textile environment.

The electronic component is preferably connected electrically to the conductor via a flexible ribbon. The flexible ribbon is a thin, flexible insulating film on which electrically conductive conductor tracks have been printed, for example, or have been structured from an originally full-area metallization by means of photographic technology and subsequent etching technology. The contact point of the electronic component is connected electrically to such a conductor track which, in turn, can be connected to the conductor of the textile material. The contact point region of the contact point with the conductor track of the flexible ribbon is protected against mechanical and chemical influences by the first encapsulation.

According to a further preferred embodiment, the electronic component is connected electrically to the conductor via a flexible metal wire. This advantageously permits, firstly, a flexible transition from the rigid component to the flexible textile material, so that no unnecessarily large surface regions of the textile material have to be stiffened. Secondly, the electric connection between contact point and conductor of the textile material opens up multifarious degrees of freedom in connecting to the conductors of the textile material and in this way permits simple adaptation of the connection pattern of the electronic component to a selected arrangement pattern of the flexible conductors in the textile fabric. Since the typical conductor period in the textile fabric is typically at least one order of magnitude greater than the typical contact point periods of electronic components, the electric connection by means of flexible metal wires permits simple expansion and adaptation of the connecting point periods.

A metal wire preferably has a diameter in the range from 50 μm to 200 μm. A metal wire which has an insulating sheath can advantageously be used. Particularly preferably, the metal wire has such an insulating sheath which has a melting or decomposition temperature which is lower than a typical soldering temperature, in particular lower than 350° C. If such a metal wire is used, then it is possible to dispense with separate electrical stripping of the wire before an electrical connecting step, if the latter is carried out as a thermal connecting step (soldering step). During the electrical connection of the metal wire to the contact point, the electric insulating sheath is destroyed thermally, so that an electrical contact can be made. Particularly preferably, the metal wire is what is known as a braided wire, as known from braiding technology.

According to a preferred embodiment, the first hard encapsulation comprises a two-component varnish or adhesive, a polyester varnish, a PU varnish, a globetop, an injection molding plastic and/or a high melting point hot melt adhesive. The aforementioned materials have proven to be particularly suitable for the mechanical stabilization and the chemical protection of the contact point region of the component.

According to a further preferred embodiment, the second encapsulation comprises a textile adhesive, preferably a hot melt adhesive, in particular a hot melt adhesive based on copolyamide or copolyester. As distinct from the first hard encapsulation, the main requirements on the second encapsulation do not lie in the mechanical and/or chemical protection of the component. Thus, a textile adhesive which is soft as compared with the first encapsulation can be used, which is preferably a special textile adhesive. The resultant “two-encapsulation structure” of the apparatus according to the invention is mechanically, chemically and thermally considerably more resistant than a “single-encapsulation structure”.

The second encapsulation particularly preferably comprises a hot melt adhesive whose melting temperature is lower than the melting temperature of the first hard encapsulation and higher than a permitted care temperature of the textile material. Mechanical connection of the textile material to the second encapsulation can be carried out without danger by means of a thermal fixing step without there being any detrimental influence on the component, in particular on its contact point region. Since the melting temperature of the second encapsulation is lower than the typical care temperature of the textile material, that is to say lower than the typical washing, cleaning and ironing temperatures, an apparatus which is more resistant to typical stresses of use results. As an alternative to the textile adhesives, soft, flexible silicones or polyurethanes can also be used.

Particularly preferably, the textile material comprises a fabric having at least one electrically conductive weft and/or warp thread, and the conductor comprises at least one electrically conductive weft and/or warp thread of the fabric. The conductors are thus woven directly into the fabric as conductive weft and/or warp threads and, in this way, are integrated optimally into the textile environment.

According to the invention, a method for connecting an electronic component to a textile comprises the steps:
providing at least one electronic component which has at least one electrically conductive contact point;
connecting the contact point electrically to a conductor track of a flexible ribbon or to a flexible metal wire;
applying at least a first hard encapsulation to the component in such a way that at least the contact point of the component is covered and mechanically stabilized;
applying at least a second encapsulation to the component and/or the first encapsulation;
fixing the component by means of the second encapsulation to a textile material in which at least one flexible, wire-like and/or thread-like electric conductor is arranged; and
connecting the conductor track of the flexible ribbon or the metal wire electrically to the wire-like and/or thread-like electric conductor.

In this case, the order of the method steps according to the invention is not fixedly predefined. For example, the conductor track of the flexible ribbon or the metal wire can be connected electrically to the flexible conductor of the textile material before the second encapsulation is carried out. The features described in conjunction with the apparatuses according to the invention described previously can advantageously likewise be used in conjunction with the method according to the invention.

### BRIEF DESCRIPTION OF THE DRAWINGS

The invention will be described by way of example in the following text with reference to accompanying drawings of preferred embodiments.

FIGS. 1(a) and 1(b) show a schematic plan and sectional view of an electronic component which is to be integrated into a textile environment;

FIGS. 2(a) and 2(b) show the electronic component from FIG. 1 with metal wires connected electrically thereto;

FIGS. 3(a) and 3(b) show the electronic component according to FIG. 1 with connected metal wires surrounded by a first hard encapsulation;

FIGS. 4(a) and 4(b) show the encapsulated component from FIG. 3 with a second encapsulation;

FIGS. 5(a) and 5(b) show an integrated circuit with first and second encapsulation; and

FIGS. 6(a) and 6(b) show an embodiment of apparatus according to the invention, the textile material being a strip fabric.

### DETAILED DESCRIPTION OF THE PREFERRED MODE OF THE INVENTION

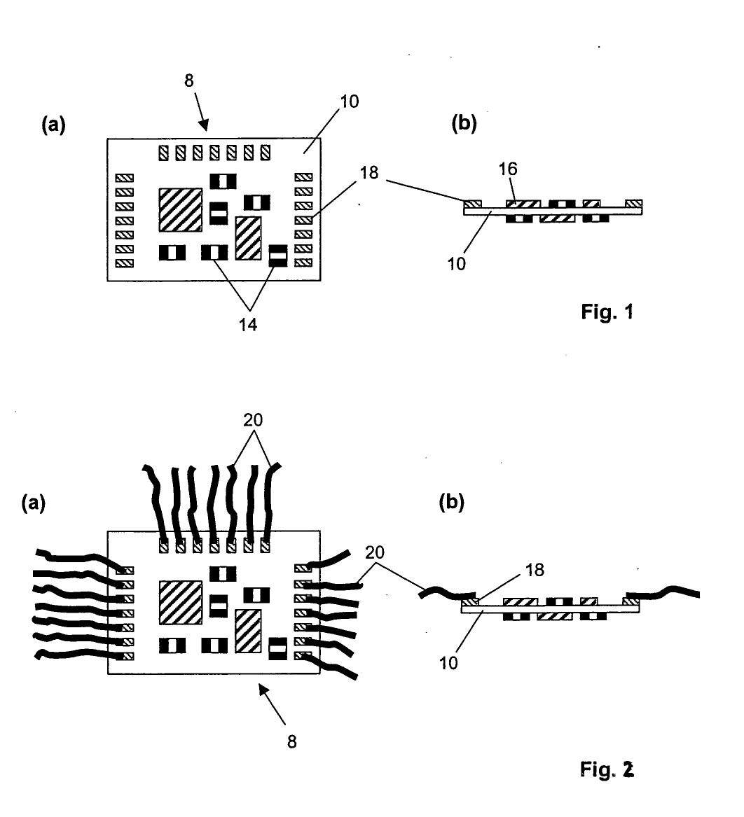

In FIG. 1, an electronic component 8 which is to be integrated into a textile environment is illustrated in plan view (a) and in sectional view (b). The electronic component 8 has a single-layer or multilayer epoxy circuit board 10. A ceramic board or a similar supporting apparatus can also be used equally well. On the circuit board 10 there are, for example, a large number of individual passive 14 and active 16 components or electronic modules. The power supply and the data input and output are carried out via a large number of preferably regularly spaced contact points 18 which, for example, are formed as bond pads or soldering platforms. The electronic component 8 is preferably as small as possible, in order in this way to stiffen only a small area in the textile environment and—as shown in the sectional view FIG. 1(b)—is fitted on both sides if necessary.

In FIG. 2, the electronic component 8 according to FIG. 1 is shown in plan view (a) and sectional view (b), thin, flexible metal wires 20 being electrically conductively connected to respective contact points 18. The wires 20 typically have a length of a few millimeters up to a few centimeters and diameters of, typically, 50 μm to 200 μm. The electrical connection of the metal wires 20 to the contact points 18 is preferably carried out by means of soldering, spot welding, ultrasonic bonding or adhesive bonding with conductive adhesive. The metal wires 20 are preferably covered with an insulating varnish which automatically dissolves or decomposes at typical soldering temperatures (about 350° C.). Metal wires 20 of this type are known from braiding technology, as it is called. In braiding technology, test circuits are built up from discrete components in such a way that the contact points of the components are connected to one another by soldering on braided wire.

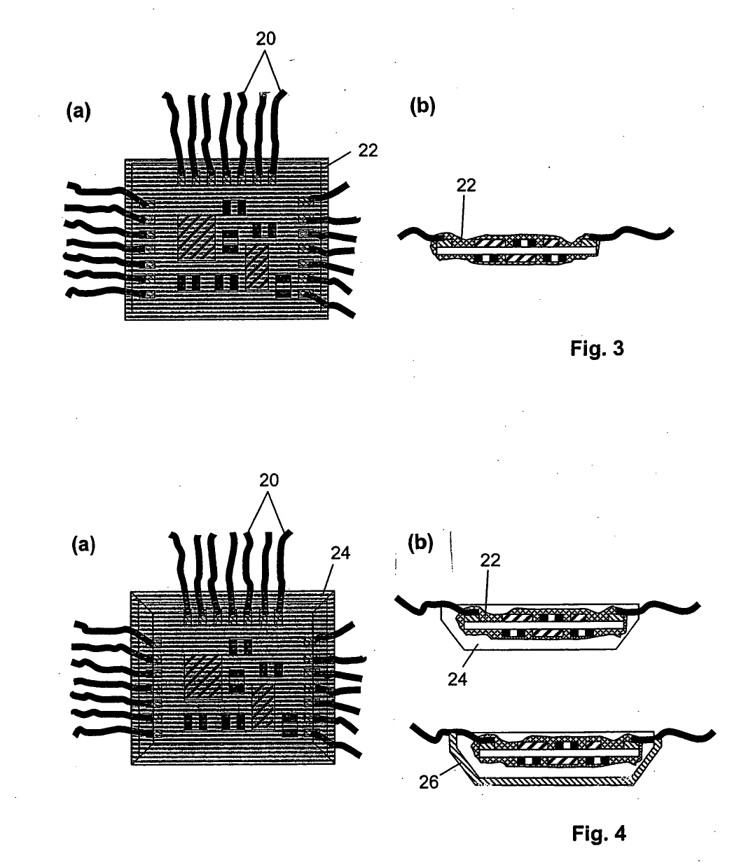

In FIG. 3, the electronic component 8 already illustrated in FIGS. 1 and 2 is shown in plan view (a) and sectional view (b) in the following process step. The electronic component 8 provided with the braided wires 20 is provided with a preferably watertight, hard encapsulation 22, which preferably covers all the individual components 14, 16 and the contact points 18. However, the first, hard encapsulation 22 can also be applied to the electronic component 8 in such a way that it covers and mechanically stabilizes only the contact points 18 to which the metal wires 20 are connected electrically.

The object of the first hard encapsulation 22 is the mechanical and preferably chemical stabilization of the electronic component 8, so that its individual components 14, 16 are protected and preferably sealed in a watertight manner. The first encapsulation 22 preferably comprises a two-component varnish or adhesive, a polyester varnish, a PU varnish, what is known as a globetop, which is often used for sealing silicon chips, injection molding plastic and/or high melting point hot melt adhesive. Typical layer thicknesses of the first encapsulation 22 are a few pm up to typically a few 100 μm.

In FIG. 4, the electronic component 8 is illustrated in plan view (a) and sectional view (b) after the following process step, in which the component 8 with the first encapsulation 22 already applied is surrounded by a second encapsulation 24. The second encapsulation 24 preferably comprises a hot melt adhesive which is designed for textile applications. The hot melt adhesive is preferably selected in such a way that its melting temperature is lower than the melting temperature of the first hard encapsulation 22 of the module, but higher than the washing and ironing temperatures permitted for the finished textile material (typically 110 to 200° C.). As an option, during the second encapsulation step, a textile covering 26 can be applied, the textile hot melt adhesive of the second encapsulation 24 preferably being used for this purpose.

The second encapsulation 24 is given its shape, for example, by being introduced into a negative casting mold of a suitable material, to which the hot melt adhesive does not adhere. Teflon has proven to be well suited. The melting temperature of the textile hot melt adhesive is selected such that it lies above the envisaged ironing temperature but the material withstands the adhesive bonding in a still undamaged state. For polyester material, 110 to 200° C. has proven to be a suitable temperature range. Typically, the second encapsulation 24 will be applied with a layer thickness in the range from a few microns to a few millimeters. Instead of the textile covering 26 specifically provided, an outer or lining material of an item of clothing can be used for the textile covering.

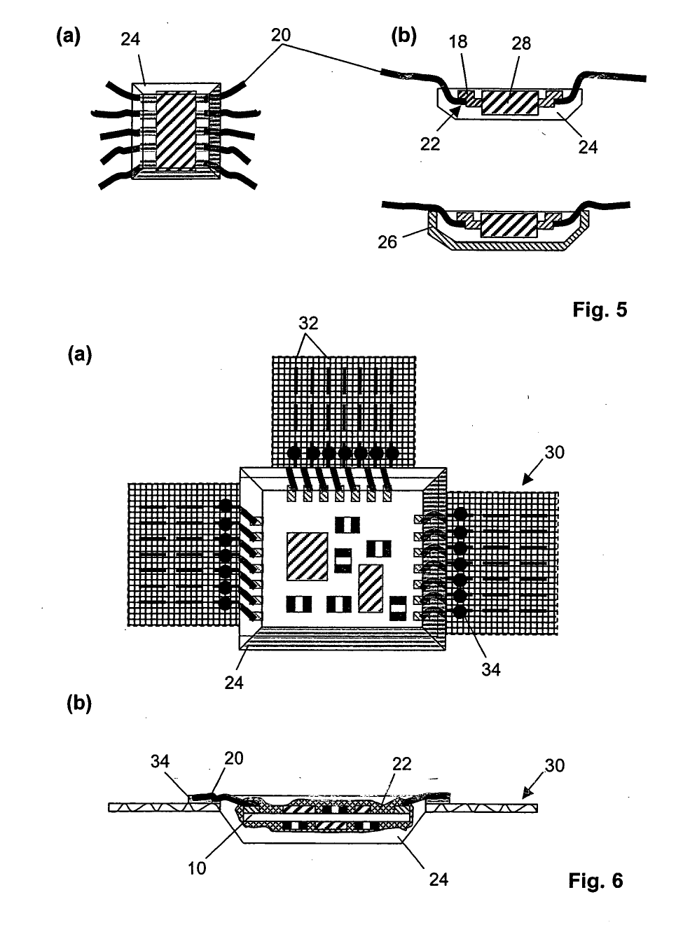

In FIG. 5, a further embodiment according to the invention is shown in plan view (a) and sectional view (b). In this case, the electronic component 8′ does not comprise a circuit board fitted with individual components but a single integrated circuit 28 which, for example, is welded into an SME housing. The flexible metal wires 20 are fitted to the contact points or legs of the SMD housing. The first hard encapsulation is in this case carried out only in the region of the contact points 18, in order to stabilize these mechanically and preferably also chemically. The processed semiconductor chip which is located in the SMD housing is sufficiently adequately protected against environmental influences by the SMD capsule. However, even in the embodiments explained in conjunction with FIGS. 1 to 4, the first encapsulation 22 can also be carried out only in the contact point region of the contact points 18. As already explained in conjunction with FIG. 4, a textile covering 26 can optionally be applied to the second encapsulation 24, in order to impart a textile “touch” to the integrated electronic component 8′. If, instead of the integrated circuit 8′, a display element (for example a 7-segment display or an LED) is fitted, the textile covering 26 is omitted and the textile hot melt adhesive of the second encapsulation 24 is selected to be transparent and applied as thinly as possible.

In FIG. 6, a preferred embodiment of an apparatus according to the invention is illustrated in plan view (a) and sectional view (b). The textile material 30 is in this case configured as a strip fabric which has electrically conductive warp and/or weft threads. Electrical connecting methods of the electrical conductors of the textile material 30 to respective conductor tracks of a flexible ribbon or the metal wires 20 are presented extensively in the German patent application DE 101 61 527.2, to whose disclosure of content reference is made completely in this regard. For the purpose of the electrical connection to the conductors 32 of the textile material 30, the metal wires 20 are shortened in accordance with the necessary lengths. The side on which the connecting points 34 are placed will preferably be selected in such a way that the textile material 30 of the item of clothing covers the connecting points 34 and in this way offers additional mechanical protection.

Using the method according to the invention for the integration of electronics in textiles, it is possible to integrate electronic components and integrated circuits permanently and washably into a textile environment and, in the process, to take account both of the requirements of the electronics (water tightness and dust tightness, specific electric connections and insulating regions, protection against pressure and bending), and the requirements of the textiles (breathable, absorbent, flexible, neutral odor, anti-allergen, completely harmless to health). Textile fabrics with conductive fibers and wires woven into them can be obtained from various manufacturers. At the present time, they are primarily used as stylistical effect fabrics, in antistatic clothing and for protection against radiation. In order to be able to use the fine, flexible metal wires woven into the textile fabric as an electrical connection, care must be taken during the fabric manufacture that the insulating protective varnish surrounding the conductors does not suffer any damage which could lead to electrical short circuits in a moist fabric state.

1. An apparatus comprising:
at least one textile material in which at least one flexible, wire-like and/or thread-like electric conductor is arranged;
at least one electronic component which has at least one electrically conductive contact point which is connected electrically to the conductor;
at least a first hard encapsulation which covers and mechanically stabilizes at least the contact point of the component; and
at least a second encapsulation, which is designed such that it permits a mechanical connection of the component to the textile material, wherein the second encapsulation comprises a silicone, a polyurethane and/or a textile adhesive.

2. The apparatus as claimed in claim 1, wherein the textile adhesive is a hot melt adhesive.

3. The apparatus as claimed in claim 1, wherein the textile adhesive is a hot melt adhesive based on copolyamide or copolyester.

4. The apparatus as claimed in claim 1, wherein the first encapsulation surrounds the component completely.

5. The apparatus as claimed in claim 1, wherein the second encapsulation surrounds the component with the first encapsulation completely.

6. The apparatus as claimed in claim 1, wherein the electronic component is connected electrically to the conductor via a flexible ribbon.

7. The apparatus as claimed in claim 1, wherein the electronic component is connected electrically to the conductor via a flexible metal wire.

8. The apparatus as claimed in claim 7, wherein the metal wire has a diameter in a range of 50 μm to 200 μm.

9. The apparatus as claimed in claim 7, wherein the metal wire has an insulating sheath.

10. The apparatus as claimed in claim 9, wherein the insulating sheath has a melting or decomposition temperature which is lower than a typical soldering temperature.

11. The apparatus as claimed in claim 9, wherein the insulating sheath has a melting or decomposition temperature which is lower than 350° C.

12. The apparatus as claimed in claim 7, wherein the metal wire is a braided wire.

13. The apparatus as claimed in claim 1, wherein the first hard encapsulation comprises a two-component varnish, a polyester varnish or adhesive, a PU varnish, a globetop, an injection molding plastic, and/or a high melting point hot melt adhesive.

14. The apparatus as claimed in claim 1, wherein the second encapsulation comprises a hot melt adhesive whose melting temperature is lower than the melting temperature of the first hard encapsulation and higher than a permitted care temperature of the textile material.

15. The apparatus as claimed in claim 1, wherein the textile material comprises a fabric having at least one electrically conductive weft and/or warp thread, and the conductor comprises at least one electrically conductive weft and/or warp thread of the fabric.

16. A method for connecting an electronic component to a textile material, comprising the steps of:
providing at least one electronic component which has at least one electrically conductive contact point;
connecting the contact point electrically to a conductor track of a flexible ribbon or to a flexible metal wire;
applying at least a first hard encapsulation to the component such that at least the contact point of the component is covered and mechanically stabilized;
applying at least a second encapsulation to the component and/or the first encapsulation, wherein the second encapsulation comprises a silicone, a polyurethane and/or a textile adhesive;
mechanically connecting the component by means of the second encapsulation to a textile material in which at least one flexible, wire-like and/or thread-like electric conductor is arranged; and
connecting the conductor track of the flexible ribbon or the metal wire electrically to the wire-like and/or thread-like electric conductor.

17. The method as claimed in claim 16, wherein the textile adhesive is a hot melt adhesive.

18. The method as claimed in claim 16, wherein the textile adhesive is a hot melt adhesive based on copolyamide or copolyester.
